(19) United States
(12) Patent Application Publication
(10) Pub. No.: US 2015/0170943 A1
(43) Pub. Date: Jun. 18, 2015

(54) SEMICONDUCTOR SYSTEM ASSEMBLIES AND METHODS OF OPERATION

(71) Applicant: Applied Materials, Inc., Santa Clara, CA (US)

(72) Inventors: Andrew Nguyen, San Jose, CA (US); Kartik Ramaswamy, San Jose, CA (US); Srinivas Nemani, Sunnyvale, CA (US); Bradley Howard, Pleasanton, CA (US); Yogananada Sarode Vishwanath, Karnataka (IN)

(73) Assignee: Applied Materials, Inc., Santa Clara, CA (US)

(21) Appl. No.: 14/108,719

(22) Filed: Dec. 17, 2013

(51) Int. Cl. H01L 21/67; H01L 21/3065

(52) U.S. Cl. CPC H01L 21/67069; H01L 21/3065

(57) ABSTRACT

An exemplary semiconductor processing system may include a processing chamber and a first plasma source. The first plasma source may utilize a first electrode positioned externally to the processing chamber, and the first plasma source may be configured to generate a first plasma. The processing system may further comprise a second plasma source separate from the first plasma source that utilizes a second electrode separate from the first electrode. The second electrode may be positioned externally to the processing chamber, and the second plasma source may be configured to generate a second plasma within the processing chamber. The processing system may further comprise a showerhead disposed between the relative locations of the first plasma electrode and the second plasma electrode.

### CROSS-REFERENCES TO RELATED APPLICATIONS

This application is related to U.S. application Ser. No. ______ (Attorney Docket No. 80042-890135 (114800US)) entitled “SEMICONDUCTOR SYSTEM ASSEMBLIES AND METHODS OF OPERATION,” and U.S. application Ser. No. ______ (Attorney Docket No. 80042-894190 (114801US)) entitled “SEMICONDUCTOR SYSTEM ASSEMBLIES AND METHODS OF OPERATION,” all of which being filed concurrently on Dec. 17, 2013, the entire disclosures of which are hereby incorporated by reference for all purposes.

### TECHNICAL FIELD

The present technology relates to semiconductor systems, processes, and equipment. More specifically, the present technology relates to systems and methods for reducing film contamination and equipment degradation.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Systems, chambers, and processes are provided for controlling chamber degradation that may in part be due to high voltage plasma. The systems may provide configurations for components that allow improved plasma profiles to be delivered. The chambers may include modified components less likely to degrade due to exposure to plasma. The methods may provide for the limiting or prevention of chamber or component degradation as a result of etching processes performed by system tools.

An exemplary semiconductor processing system may include a processing chamber and a first plasma source. The first plasma source may utilize a first electrode positioned externally to the processing chamber, and the first plasma source may be configured to generate a first plasma. The processing system may further comprise a second plasma source separate from the first plasma source that utilizes a second electrode separate from the first electrode. The second electrode may be positioned externally to the processing chamber, and the second plasma source may be configured to generate a second plasma within the processing chamber. The processing system may further include a showerhead disposed between the relative locations of the first plasma electrode and the second plasma electrode.

Exemplary processing systems may further include a second showerhead positioned fluidly downstream from the location at which the second plasma is configured to be generated, and the second showerhead may include a multi-channel showerhead in embodiments. An insulator may be positioned between the first showerhead and the second showerhead in disclosed embodiments. The second plasma source may include an inductively coupled plasma source, and in embodiments the inductively coupled plasma source may include at least two separate coils arranged about the processing chamber. In disclosed embodiments, the inductively coupled plasma source may include at least four separate coils arranged about the processing chamber, and the at least four separate coils may be displaced about the processing chamber from each other by about 90°. In embodiments the second showerhead may be positioned fluidly upstream from a location at which the inductively coupled plasma may be configured to be generated. In exemplary semiconductor processing systems, the first plasma source may be electrically coupled with a first RF source, and the second plasma source may be electrically coupled with a second RF source separate from the first RF source. In embodiments, the first RF source may be configured to operate at a first plasma frequency, and the second RF source may be configured to operate at a second plasma frequency greater than the first plasma frequency.

Semiconductor processing systems are also described that include a processing chamber having a top plate in a plasma generation device coupled with the top plate. In disclosed embodiments, the plasma generation device may include a plasma generation device housing, and a nozzle positioned within the plasma generation device housing. The nozzle may also include a fluid injection port, and the nozzle may be composed partially, substantially, or exclusively of an insulative material. The plasma generation device may also include a plasma electrode positioned within the plasma generation device housing and coupled externally with the nozzle. The plasma electrode may be coupled with a plasma source and be configured to generate a plasma within the nozzle. In disclosed embodiments, the plasma electrode may include at least two separate coils arranged about the nozzle.

Methods of etching are also described and may include striking a first plasma with a first plasma source operating as an inductively coupled plasma source. The methods may include creating a flux of nonreactive ions, and delivering the ions to a processing chamber in which a substrate is housed. The methods may also include etching materials on the substrate. The methods may further include striking a second plasma with a second plasma source separate from the first plasma source to create plasma effluents of a first precursor. The methods may also include bypassing the second plasma with a second precursor. The methods may include contacting the second precursor with the plasma effluents of the first precursor to produce an etching formula. The etching formula may be delivered through the processing chamber to the substrate and materials on the substrate may be etched with the etching formula.

Such technology may provide numerous benefits over conventional systems and techniques. For example, degradation of the electrode and other chamber components may be prevented or limited. An additional advantage is that improved etching profiles may be provided based on improved plasma control. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to the present technology.

FIG. 2 shows a schematic cross-sectional view of an exemplary processing chamber according to the present technology.

FIG. 3 shows a schematic cross-sectional view of a portion of an exemplary processing chamber according to the disclosed technology.

FIG. 4 shows a bottom plan view of a showerhead according to the disclosed technology.

FIG. 5 shows a schematic cross-sectional view of a portion of an exemplary processing chamber according to the disclosed technology.

FIG. 6 shows a schematic cross-sectional view of a portion of an exemplary processing chamber according to the disclosed technology.

FIG. 7 shows a schematic cross-sectional view of a portion of an exemplary processing chamber according to the disclosed technology.

FIG. 8 shows a schematic view of a portion of a plasma coil according to the disclosed technology.

FIG. 9 shows a schematic cross-sectional view of a portion of an exemplary plasma generation device according to the disclosed technology.

FIG. 10 shows a method of etching that may reduce film contamination according to the present technology.

Several of the Figures are included as schematics. It is to be understood that the Figures are for illustrative purposes, and are not to be considered of scale unless specifically stated to be as such.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

The present technology includes systems and components for semiconductor processing. When plasmas are formed in situ in processing chambers, such as with a capacitively coupled plasma (“CCP”) for example, exposed surfaces of the chamber may be sputtered or degraded by the plasma or the species produced by the plasma. This may in part be caused by bombardment to the surfaces or surface coatings by generated plasma particles. The extent of the bombardment may itself be related to the voltage utilized in generating the plasma. For example, higher voltage may cause higher bombardment, and further degradation.

Conventional technologies have often dealt with this degradation by providing replaceable components within the chamber. Accordingly, when coatings or components themselves are degraded, the component may be removed and replaced with a new component that will in turn degrade over time. By utilizing configurations in which plasma is formed externally to the chamber, or in which the plasma electrode is positioned externally to the chamber, multiple benefits or advantages may be provided. For example, the electrode positioned outside of the chamber may have reduced corrosion as it may not be exposed to plasma. Additionally, forming certain plasmas externally to the chamber may reduce degradation of internal chamber components over time. Accordingly, the systems described herein provide improved performance and cost benefits over many conventional designs. These and other benefits will be described in detail below.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes alone.

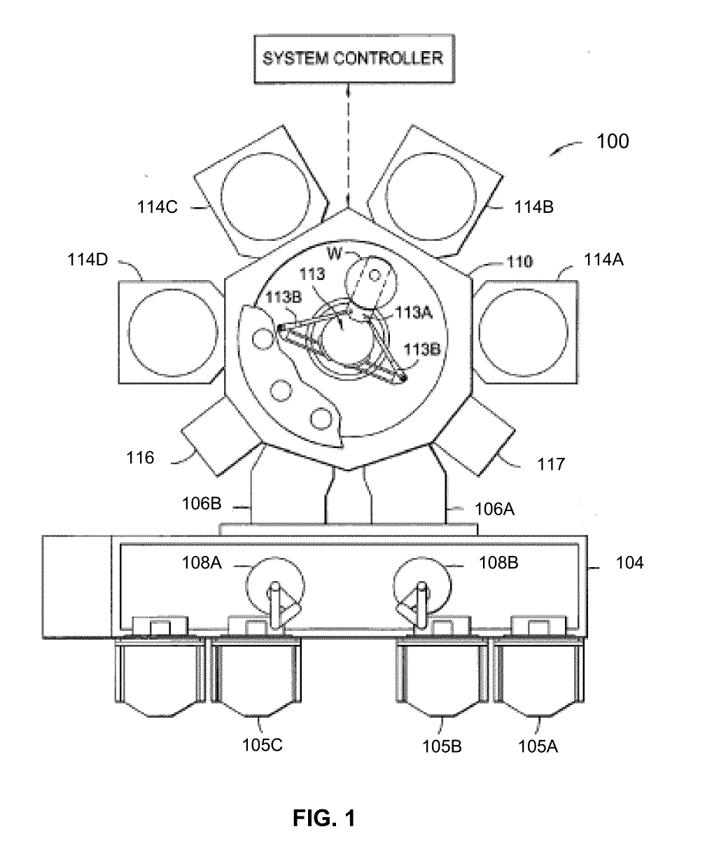

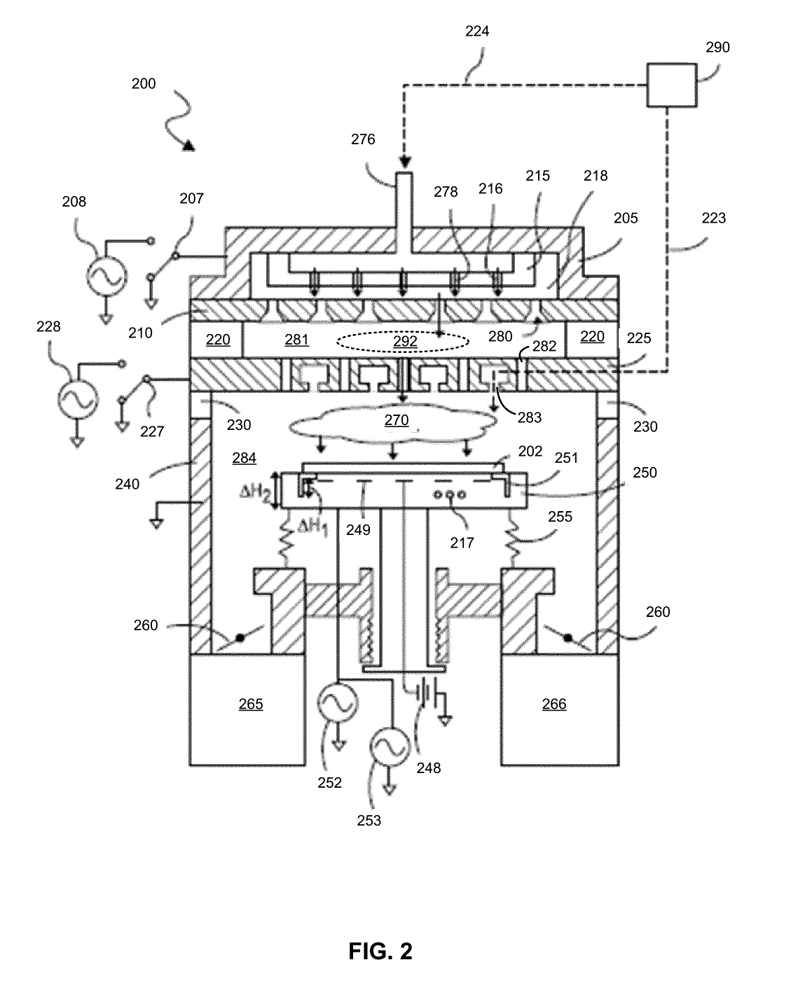

FIG. 1 shows a top plan view of one embodiment of a processing system 100 of deposition, etching, baking, and curing chambers according to embodiments. The processing tool 100 depicted in FIG. 1 may contain a plurality of process chambers, 114A-D, a transfer chamber 110, a service chamber 116, an integrated metrology chamber 117, and a pair of load lock chambers 106A-B. The process chambers may include structures or components similar to those described in relation to FIG. 2, as well as additional processing chambers.

To transport substrates among the chambers, the transfer chamber 110 may contain a robotic transport mechanism 113. The transport mechanism 113 may have a pair of substrate transport blades 113A attached to the distal ends of extendible arms 113B, respectively. The blades 113A may be used for carrying individual substrates to and from the process chambers. In operation, one of the substrate transport blades such as blade 113A of the transport mechanism 113 may retrieve a substrate W from one of the load lock chambers such as chambers 106A-B and carry substrate W to a first stage of processing, for example, an etching process as described below in chambers 114A-D. If the chamber is occupied, the robot may wait until the processing is complete and then remove the processed substrate from the chamber with one blade 113A and may insert a new substrate with a second blade (not shown). Once the substrate is processed, it may then be moved to a second stage of processing. For each move, the transport mechanism 113 generally may have one blade carrying a substrate and one blade empty to execute a substrate exchange. The transport mechanism 113 may wait at each chamber until an exchange can be accomplished.

Once processing is complete within the process chambers, the transport mechanism 113 may move the substrate W from the last process chamber and transport the substrate W to a cassette within the load lock chambers 106A-B. From the load lock chambers 106A-B, the substrate may move into a factory interface 104. The factory interface 104 generally may operate to transfer substrates between pod loaders 105A-D in an atmospheric pressure clean environment and the load lock chambers 106A-B. The clean environment in factory interface 104 may be generally provided through air filtration processes, such as HEPA filtration, for example. Factory interface 104 may also include a substrate orienter/aligner (not shown) that may be used to properly align the substrates prior to processing. At least one substrate robot, such as robots 108A-B, may be positioned in factory interface 104 to transport substrates between various positions/locations within factory interface 104 and to other locations in communication therewith. Robots 108A-B may be configured to travel along a track system within enclosure 104 from a first end to a second end of the factory interface 104.

The processing system 100 may further include an integrated metrology chamber 117 to provide control signals, which may provide adaptive control over any of the processes being performed in the processing chambers. The integrated metrology chamber 117 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Turning now to FIG. 2 is shown a cross-sectional view of an exemplary process chamber system 200 according to the present technology. Chamber 200 may be used, for example, in one or more of the processing chamber sections 114 of the system 100 previously discussed Generally, the etch chamber 200 may include a first capacitively-coupled plasma source to implement an ion milling operation and a second capacitively-coupled plasma source to implement an etching operation and to implement an optional deposition operation. The chamber 200 may include grounded chamber walls 240 surrounding a chuck 250. In embodiments, the chuck 250 may be an electrostatic chuck that clamps the substrate 202 to a top surface of the chuck 250 during processing, though other clamping mechanisms as would be known may also be utilized. The chuck 250 may include an embedded heat exchanger coil 217. In the exemplary embodiment, the heat exchanger coil 217 includes one or more heat transfer fluid channels through which heat transfer fluid, such as an ethylene glycol/water mix, may be passed to control the temperature of the chuck 250 and ultimately the temperature of the substrate 202.

The chuck 250 may include a mesh 249 coupled to a high voltage DC supply 248 so that the mesh 249 may carry a DC bias potential to implement the electrostatic clamping of the substrate 202. The chuck 250 may be coupled with a first RF power source and in one such embodiment, the mesh 249 may be coupled with the first RF power source so that both the DC voltage offset and the RF voltage potentials are coupled across a thin dielectric layer on the top surface of the chuck 250. In the illustrative embodiment, the first RF power source may include a first and second RF generator 252, 253. The RF generators 252, 253 may operate at any industrially utilized frequency, however in the exemplary embodiment the RF generator 252 may operate at 60 MHz to provide advantageous directionality. Where a second RF generator 253 is also provided, the exemplary frequency may be 2 MHz.

With the chuck 250 to be RF powered, an RF return path may be provided by a first showerhead 225. The first showerhead 225 may be disposed above the chuck to distribute a first feed gas into a first chamber region 284 defined by the first showerhead 225 and the chamber wall 240. As such, the chuck 250 and the first showerhead 225 form a first RF coupled electrode pair to capacitively energize a first plasma 270 of a first feed gas within a first chamber region 284. A DC plasma bias, or RF bias, resulting from capacitive coupling of the RF powered chuck may generate an ion flux from the first plasma 270 to the substrate 202, e.g., Ar ions where the first feed gas is Ar, to provide an ion milling plasma. The first showerhead 225 may be grounded or alternately coupled with an RF source 228 having one or more generators operable at a frequency other than that of the chuck 250, e.g., 13.56 MHz or 60 MHz. In the illustrated embodiment the first showerhead 225 may be selectably coupled to ground or the RF source 228 through the relay 227 which may be automatically controlled during the etch process, for example by a controller (not shown). In disclosed embodiments, chamber 200 may not include showerhead 225 or dielectric spacer 220, and may instead include only baffle 215 and showerhead 210 described further below.

As further illustrated in the figure, the etch chamber 200 may include a pump stack capable of high throughput at low process pressures. In embodiments, at least one turbo molecular pump 265, 266 may be coupled with the first chamber region 284 through one or more gate valves 260 and disposed below the chuck 250, opposite the first showerhead 225. The turbo molecular pumps 265, 266 may be any commercially available pumps having suitable throughput and more particularly may be sized appropriately to maintain process pressures below or about 10 mTorr or below or about 5 mTorr at the desired flow rate of the first feed gas, e.g., 50 to 500 sccm of Ar where argon is the first feedgas. In the embodiment illustrated, the chuck 250 may form part of a pedestal which is centered between the two turbo pumps 265 and 266, however in alternate configurations chuck 250 may be on a pedestal cantilevered from the chamber wall 240 with a single turbo molecular pump having a center aligned with a center of the chuck 250.

Disposed above the first showerhead 225 may be a second showerhead 210. In one embodiment, during processing, the first feed gas source, for example, Argon delivered from gas distribution system 290 may be coupled with a gas inlet 276, and the first feed gas flowed through a plurality of apertures 280 extending through second showerhead 210, into the second chamber region 281, and through a plurality of apertures 282 extending through the first showerhead 225 into the first chamber region 284. An additional flow distributor or baffle 215 having apertures 278 may further distribute a first feed gas flow 216 across the diameter of the etch chamber 200 through a distribution region 218. In an alternate embodiment, the first feed gas may be flowed directly into the first chamber region 284 via apertures 283 which are isolated from the second chamber region 281 as denoted by dashed line 223.

Chamber 200 may additionally be reconfigured from the state illustrated to perform an etching operation. A secondary electrode 205 may be disposed above the first showerhead 225 with a second chamber region 281 there between. The secondary electrode 205 may further form a lid or top plate of the etch chamber 200. The secondary electrode 205 and the first showerhead 225 may be electrically isolated by a dielectric ring 220 and form a second RF coupled electrode pair to capacitively discharge a second plasma 292 of a second feed gas within the second chamber region 281. Advantageously, the second plasma 292 may not provide a significant RF bias potential on the chuck 250. At least one electrode of the second RF coupled electrode pair may be coupled with an RF source for energizing an etching plasma. The secondary electrode 205 may be electrically coupled with the second showerhead 210. In an exemplary embodiment, the first showerhead 225 may be coupled with a ground plane or floating and may be coupled to ground through a relay 227 allowing the first showerhead 225 to also be powered by the RF power source 228 during the ion milling mode of operation. Where the first showerhead 225 is grounded, an RF power source 208, having one or more RF generators operating at 13.56 MHz or 60 MHz, for example, may be coupled with the secondary electrode 205 through a relay 207 which may allow the secondary electrode 205 to also be grounded during other operational modes, such as during an ion milling operation, although the secondary electrode 205 may also be left floating if the first showerhead 225 is powered.

A second feed gas source, such as nitrogen trifluoride, and a hydrogen source, such as ammonia, may be delivered from gas distribution system 290, and coupled with the gas inlet 276 such as via dashed line 224. In this mode, the second feed gas may flow through the second showerhead 210 and may be energized in the second chamber region 281. Reactive species may then pass into the first chamber region 284 to react with the substrate 202. As further illustrated, for embodiments where the first showerhead 225 is a multi-channel showerhead, one or more feed gases may be provided to react with the reactive species generated by the second plasma 292. In one such embodiment, a water source may be coupled with the plurality of apertures 283.

In an embodiment, the chuck 250 may be movable along the distance H2 in a direction normal to the first showerhead 225. The chuck 250 may be on an actuated mechanism surrounded by a bellows 255, or the like, to allow the chuck 250 to move closer to or farther from the first showerhead 225 as a means of controlling heat transfer between the chuck 250 and the first showerhead 225, which may be at an elevated temperature of 80° C.-150° C., or more. As such, an etch process may be implemented by moving the chuck 250 between first and second predetermined positions relative to the first showerhead 225. Alternatively, the chuck 250 may include a lifter 251 to elevate the substrate 202 off a top surface of the chuck 250 by distance H1 to control heating by the first showerhead 225 during the etch process. In other embodiments, where the etch process is performed at a fixed temperature such as about 90-110° C. for example, chuck displacement mechanisms may be avoided. A system controller (not shown) may alternately energize the first and second plasmas 270 and 292 during the etching process by alternately powering the first and second RF coupled electrode pairs automatically.

The chamber 200 may also be reconfigured to perform a deposition operation. A plasma 292 may be generated in the second chamber region 281 by an RF discharge which may be implemented in any of the manners described for the second plasma 292. Where the first showerhead 225 is powered to generate the plasma 292 during a deposition, the first showerhead 225 may be isolated from a grounded chamber wall 240 by a dielectric spacer 230 so as to be electrically floating relative to the chamber wall. In the exemplary embodiment, an oxidizer feed gas source, such as molecular oxygen, may be delivered from gas distribution system 290, and coupled with the gas inlet 276. In embodiments where the first showerhead 225 is a multi-channel showerhead, any silicon-containing precursor, such as OMCTS for example, may be delivered from gas distribution system 290, and directed into the first chamber region 284 to react with reactive species passing through the first showerhead 225 from the plasma 292. Alternatively the silicon-containing precursor may also be flowed through the gas inlet 276 along with the oxidizer.

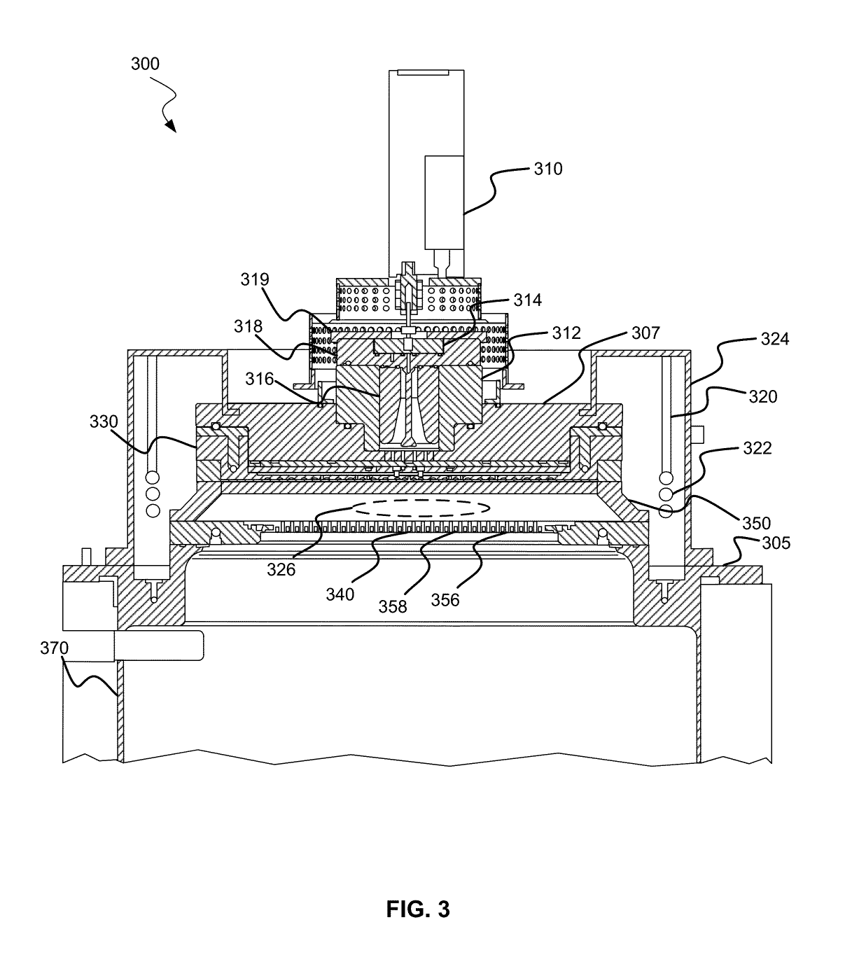

FIG. 3 shows a schematic cross-sectional view of a portion of an exemplary processing system 300 according to the disclosed technology. As illustrated, system 300 includes a more detailed view of an exemplary version of a top portion and related components of, for example, system 200 as previously described. Semiconductor processing system 300 may include a processing chamber 305, as well as a first plasma source 310 configured to generate a first plasma. Via an inlet gas assembly, first plasma source 310 may be coupled with a processing chamber 305 including top plate 307, which may be similar in aspects to top cover 205 as previously described. The inlet gas assembly may include a number of components utilized in generating the plasma and delivering precursors into chamber 305. The inlet gas assembly may be coupled with the top plate 307 via an insulator 312 that may be configured to electrically insulate the top plate 307 from a first electrode 314. First electrode 314 may be made of a variety of conductive materials and metals, and in embodiments may include coatings, such as metal coatings including transition metals, including nickel, for example. As shown in the figure, first plasma source 310 utilizing first electrode 314 may both be positioned externally to the processing chamber in disclosed embodiments.

Inlet insulator 312 may define an opening in which may be positioned a nozzle 316 configured to deliver precursors for plasma processing. As the nozzle 316 typically aids plasma generation as well, the nozzle 316 may include metal or conductive components. As illustrated in the figure, nozzle 316 may define a channel extending through the device, which may be configured to affect the flow of precursors being delivered. Such a configuration may affect the precursor distribution in plasma generation, which may aid uniformity of the plasma within the processing chamber 305. System 300 may further include an ignition rod 318 as part of the inlet assembly. Ignition rod 318 may be positioned between the electrode 314 and the nozzle 316, and at least a portion of the ignition rod 318 may extend into the channel defined by the nozzle 316.

Ignition rod 318 may define an opening, and electrode 314 may be located at least partially within the opening and be seated within the ignition rod 318. Processing system 300 may further include an RF insulator 319 positioned between the first plasma source 305 and ignition rod 318, which may operate to further electrically isolate the components of the inlet assembly. Both RF insulator 319 and inlet insulator 312 may be composed of a variety of dielectric or other insulating materials including ceramic in disclosed embodiments.

Semiconductor processing system 300 may include a second plasma source 320 separate from first plasma source 310. Second plasma source 320 may utilize a second electrode 322 separate from first electrode 314. As illustrated, the second electrode 322 may also be positioned externally to processing chamber 305, but may be contained within a plasma shield 324. Second plasma source 320 may be configured to generate a second plasma within the processing chamber 305 such as within an internal plasma region 326. Semiconductor processing system 300 may further include a first showerhead 330 disposed between the first plasma electrode 314 and the second plasma electrode 322. The system 300 may further include a second showerhead 340 positioned fluidly downstream from the location in which the second plasma is configured to be generated, such as region 326. Semiconductor processing system 300 may further include an insulator 350 positioned between the first showerhead 330 and the second showerhead 340.

Second plasma source 320 may include an inductively coupled plasma source in disclosed embodiments. As such, electrode 322 may include a coil design in which the electrode is wrapped about the chamber, such as about insulative section 350. In embodiments, electrode 322 may include a variety of metals or conductive materials, and insulator 350 may include ceramic or other insulative materials. In operation, second plasma source 320 may be used to generate a plasma that may be utilized for a variety of purposes including the ion milling operation previously described. For example, second plasma source 320 may be utilized to generate a second plasma in region 326. The precursor may be delivered into region 326 to create a flux of nonreactive ions. The precursors used may include argon, helium, hydrogen, nitrogen, and additional inert or alternatively reactive precursors. The generated flux of ions may be delivered through second showerhead 340 into a region of processing chamber 305 in which a substrate may be housed such as region 370, and an ion milling operation such as previously described may be performed on the substrate or materials on the substrate.

The first plasma source 310 may then be energized to generate a first plasma about and downstream of nozzle 316. Additional precursors, which may include a fluorine-containing precursor, may be delivered to nozzle 316 and may be energized by the first plasma to create effluents that may be utilized in an etching operation. These effluents may be contacted with an additional precursor that may have bypassed first plasma source 310, and an etching formula may be produced. This etching formula may then be delivered to a substrate contained in chamber processing region 370 to perform a selective etch against multiple materials that may be exposed on the substrate. Compared to the configuration as discussed with respect to FIG. 2, the exemplary configuration of FIG. 3, as well as the exemplary method here described, may be utilized to increase throughput of substrates such as semiconductor devices.

For example, the exemplary method discussed with respect to FIG. 2 may include a modular operation of ion milling and selective etching in which one or the other of the two plasmas is energized and an operation is performed. With the configuration of FIG. 3, however, second plasma source 320 may be maintained during the selective etching operation in disclosed embodiments. Second plasma source 320 may produce a high-density plasma within a region 326 that may be used to further process the effluents generated by first plasma source 310. Additionally, because the precursor that bypasses first plasma source 310 may be delivered through showerhead 340, it may also bypass the second plasma generated in region 326. Two benefits of such an operational configuration include that plasma effluents generated by first plasma source 310 may have reduced recombination along the flow path because the second plasma produced in region 326 may help maintain the desired ionization. Moreover, because plasma switching may not need to be performed, substrate throughput may be increased as the time between successive operations may be reduced.

First plasma source 310 and second plasma source 320 may operate at any number of frequencies useful for producing plasma, including variable frequencies. First plasma source 310 may be electrically coupled with a first RF source, for example, and second plasma source 320 may be electrically coupled with a second RF source separate from the first RF source. In disclosed embodiments, the first plasma electrical source 310 may be configured to operate at frequencies of up to, less than, or at least about 5 kHz, 10 kHz, 50 kHz, 100 kHz, 500 kHz, 1 MHz, 13.56 MHz, 60 MHz, etc. or higher, or any frequency between any of these stated frequencies. In one embodiment, for example, the first plasma source 310 may be operated within a range of between about 5 kHz-10 kHz. Second plasma source 320 may be operated at a similar or different frequency than first plasma source 310. For example, the first RF source may be configured to operate at a first plasma power, and the second RF source may be configured to operate at a plasma power greater than the first plasma power. In disclosed embodiments, the second plasma source 310 may be configured to operate at frequencies of up to, less than, or at least about 100 kHz, 1 MHz, 13.56 MHz, 40 MHz, 60 MHz, 100 MHz, 500 MHz, 1000 MHz, 2450 MHz, etc. or higher, or any frequency between any of these stated frequencies. In one embodiment, for example, the second plasma source 320 may be operated within a range of between about 40 MHz-100 MHz.

As previously discussed, second showerhead 340 may be positioned downstream of plasma region 326 and may allow plasma effluents or excited derivatives of precursors or other gases created within chamber plasma region 326 or the first plasma source 310 to pass through a plurality of through-holes 356 that traverse the thickness of the plate or plates included in the showerhead. The showerhead 340 may also have one or more hollow volumes that can be filled with a precursor in the form of a vapor or gas, such as a nitrogen-containing precursor, and pass through holes 358 into substrate processing region 370, but not directly into chamber plasma region 326. In order to maintain a significant concentration of excited species penetrating from chamber plasma region 326 to substrate processing region 370, the length of the smallest diameter of the through-holes may be restricted by forming larger diameter portions of through-holes 356 part way through the showerhead 340. The length of the smallest diameter of the through-holes 356 may be the same order of magnitude as the smallest diameter of the through-holes 356 or less in disclosed embodiments.

In the embodiment shown, showerhead 340 may distribute, via through-holes 356, process gases which may contain a plasma vapor/gas such as argon, or a fluorine-containing precursor, for example. Additionally, the showerhead 340 may distribute, via smaller holes 358, a nitrogen-containing precursor that is maintained separately from the plasma region 326. The process gas or gases and the nitrogen containing precursor may be maintained fluidly separate via the showerhead 340 until the precursors separately enter the processing region 370. The precursors may contact one another once they enter the processing region and react to form an etching formula that may be used to selectively etch materials on a substrate.

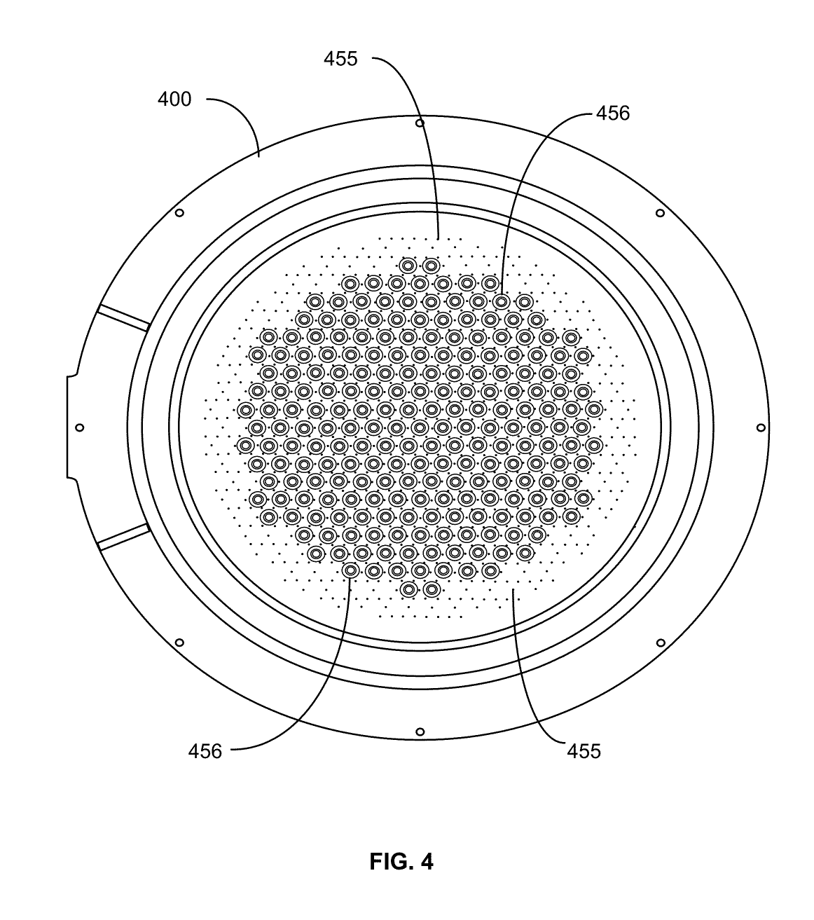

FIG. 4 shows a bottom plan view of a showerhead 400 according to the disclosed technology. Showerhead 400 may correspond with the showerhead shown in FIG. 3. Through-holes 456 are depicted with a larger inner-diameter (ID) on the bottom of showerhead 400 and a smaller ID at the top. Small holes 455 are distributed substantially evenly over the surface of the showerhead, even amongst the through-holes 456 which may help to provide more even mixing than other embodiments.

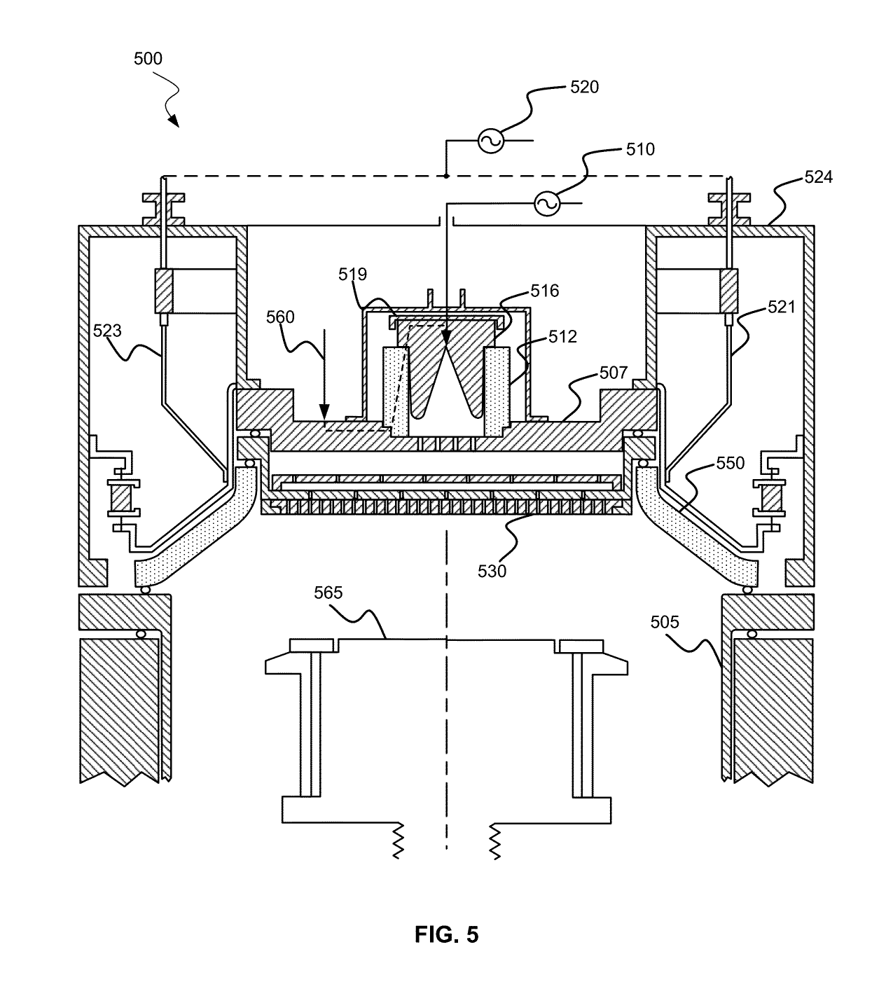

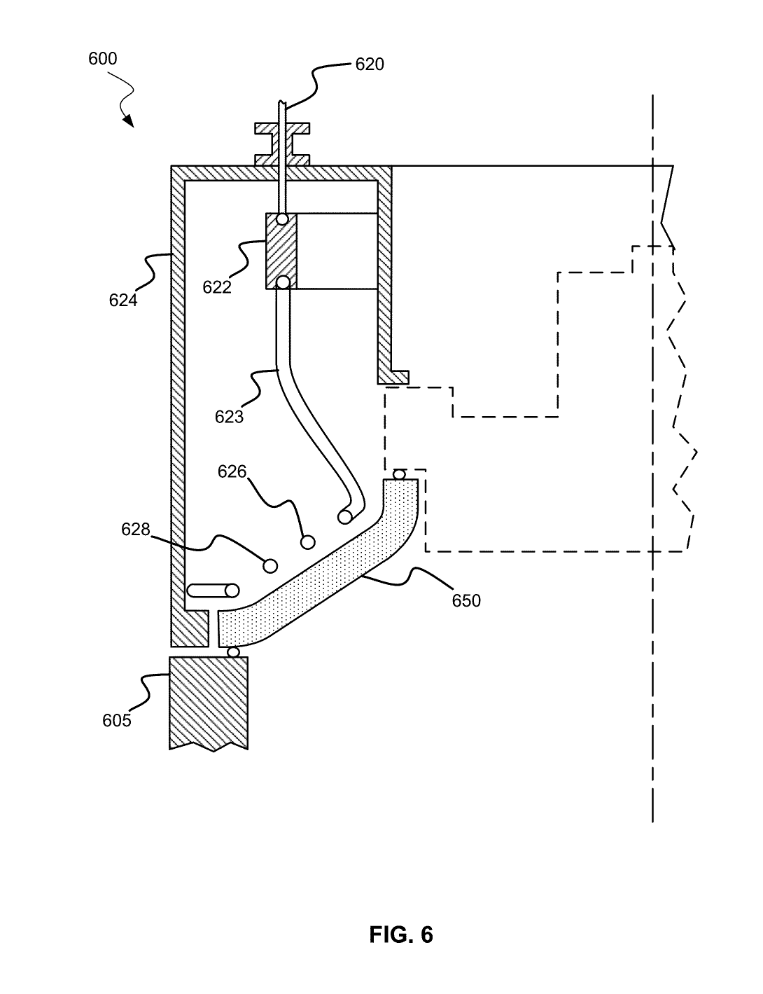

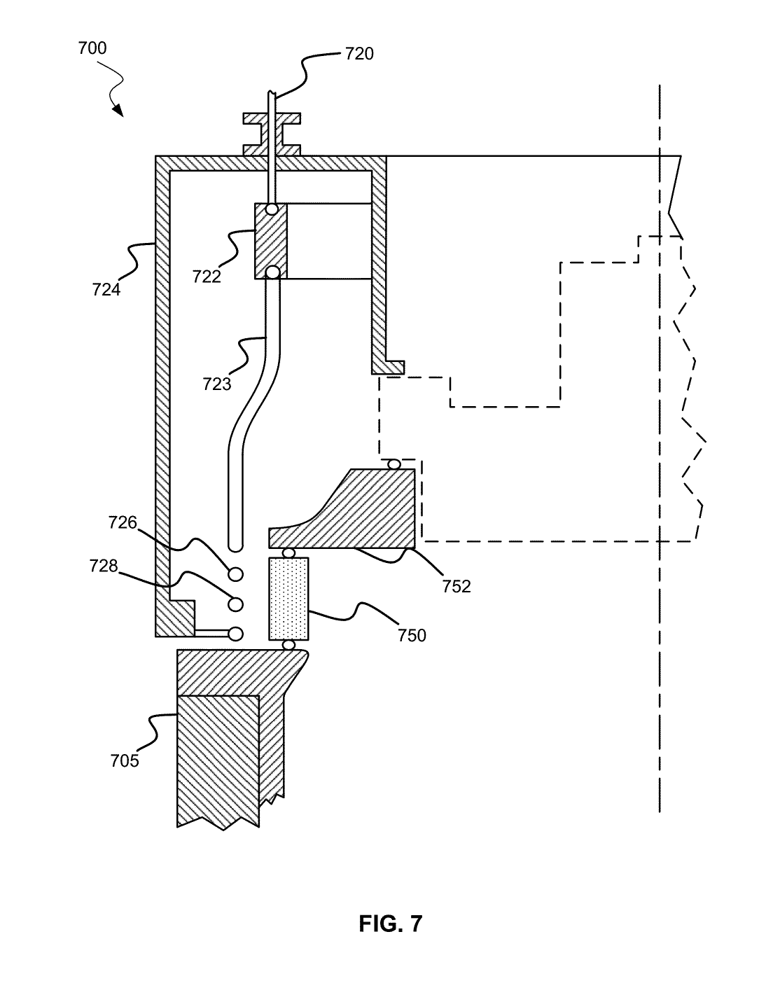

Turning to FIG. 5, shown is a schematic cross-sectional view of a portion of an exemplary processing system 500 according to the disclosed technology, which includes a detailed interpretation of first plasma source 310 and second plasma source 320 previously described. Accordingly, semiconductor processing system 500 may include similar components as system 300 including a processing chamber 505 having a top plate 507 with which a first plasma source 510 may be coupled. First plasma source 510 may be coupled with the top plate 507 via an inlet gas assembly including inlet insulator 512, nozzle 516, and RF insulator 519. Semiconductor processing system 500 further may include a precursor distributor 560 which may be utilized to deliver one or more precursors to nozzle 516. System 500 may still further include at least one showerhead 530, an insulator section 550, additional versions of which are illustrated in FIGS. 6 and 7. One or more additional showerheads may also be included, including a multi-channel showerhead, although not shown in the figure. Such a showerhead may allow multiple precursors to be provided through separated channels while remaining fluidly separated from each other until leaving the showerhead. Also shown in the illustration is a pedestal 565, which may be used to support a substrate via, for example, an electrostatic chuck. Although processing system 500 may include an additional showerhead positioned below insulator section 515, in disclosed embodiments showerhead 530 may be a second showerhead positioned in the system that is disposed fluidly upstream from the location at which a second plasma, such as an inductively coupled plasma, may be configured to be generated.

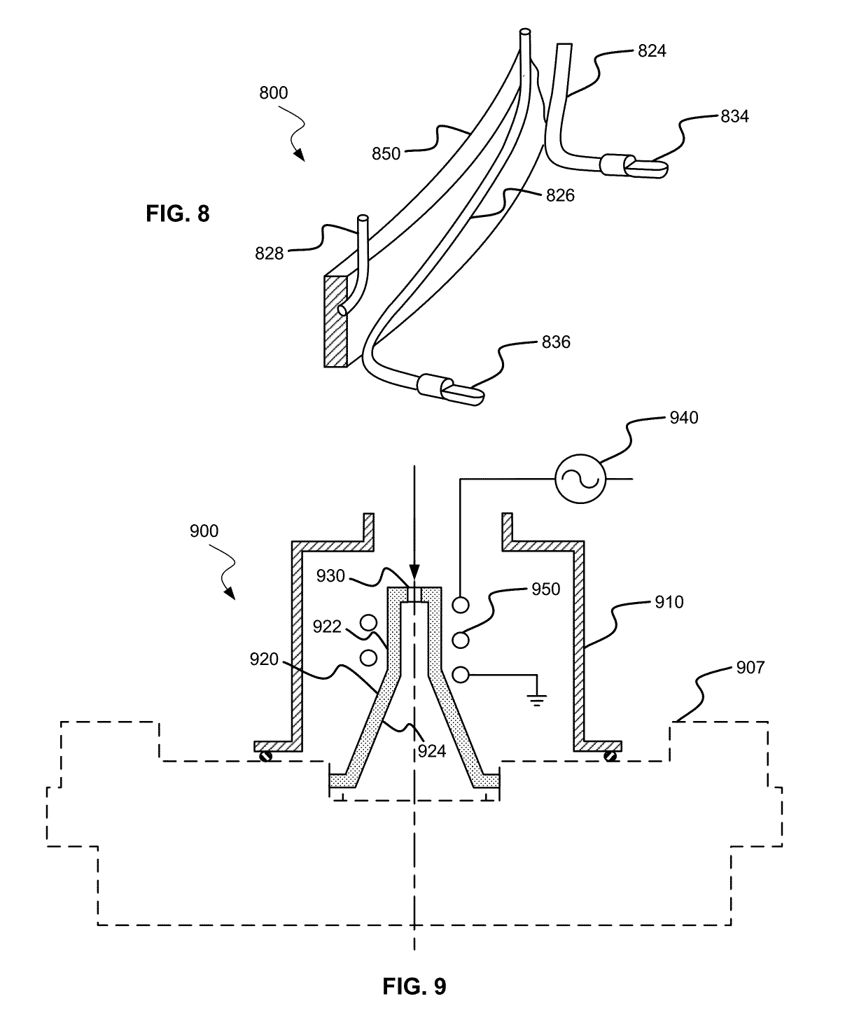

Semiconductor processing system 500 may additionally include a second plasma source 520, such as an inductively coupled plasma source, coupled with an exterior portion of semiconductor processing chamber 505 and housed by external shield 524. Second plasma source 520 may distribute power to one or more electrodes about processing chamber 505. As illustrated, second plasma source 520 may distribute power to at least two separate electrodes 521, 523 distributed about the chamber. Each of these electrodes may be configured as a coil distributed about at least a portion of processing chamber 505 as spokes from second plasma source 520. In disclosed embodiments, second plasma source 520 may include at least four separate electrodes or coils arranged about the processing chamber, which will be discussed further below with reference to FIG. 8.

Turning to FIG. 6, shown is a schematic cross-sectional view of a portion of an exemplary processing chamber 600 according to the disclosed technology, which illustrates further detail that may be associated with a second plasma source. A plasma source 620, such as a second plasma source as previously described, may be distributed about processing chamber 605 via an RF ring 622 and one or more electrodes 623, which may be housed by shield 624. Electrode 623 may be at least partially coiled about processing chamber 605, such as around insulative section 650. Insulative section 650 may be composed of a variety of insulative materials including ceramics, and may be shaped to define an area within processing chamber 605 in which a plasma may be generated. As illustrated, insulative section 650 may be annular in shape, and may include an at least partially domed structure to define the plasma region. Electrode 623 may be coupled about insulative section 650 one or more times to provide a coiled structure. In disclosed embodiments, multiple electrodes may be coiled about processing chamber 605, and may at least partially overlap with one another. Accordingly, coils 626 and 628 may in embodiments be part of electrode 623 or may be one or more separate electrodes from electrode 623.

FIG. 7 shows a schematic cross-sectional view of a portion of another exemplary processing chamber according to the disclosed technology, which illustrates additional detail that may be associated with a second plasma source. A plasma source 720, such as a second plasma source as previously described, may be distributed about processing chamber 705 via an RF ring 722 and an electrode 723, which may be housed by shield 724. Electrode 723 may be at least partially coiled about processing chamber 705, such as around insulative section 750. Insulative section 750 may be composed of a variety of insulative materials including ceramics, and may be shaped to define an area within processing chamber 705 in which a plasma may be generated. As illustrated, insulative section 750 may be annular in shape, and may be positioned below additional metal structures or components such as plate 752, which may further define a plasma region in which second plasma source 720 may generate a second plasma within the processing chamber. Electrode 723 may be coupled about insulative section 750 one or more times to provide a coiled structure. In disclosed embodiments, multiple electrodes may be coiled about processing chamber 705, and may at least partially overlap with one another. Accordingly, coils 726 and 728 may in embodiments be part of electrode 723 or may be one or more separate electrodes from electrode 723.

FIG. 8 shows a schematic view of a portion of a plasma coil 800 according to the disclosed technology. As illustrated, one or more electrodes may be distributed about insulative section 850. Insulative section 850 may include any of the designs previously described. Electrodes 824, 826, 828, may each be powered separately by a plasma source, such as a second plasma source as previously described, and may additionally include separate outlet connections such as outlet portions 834, 836, for example. The electrodes may be utilized to produce an inductively coupled plasma within a processing chamber. In designs in which a single electrode is coiled about a processing chamber, the generated plasma may not have a uniform profile across the plasma area, which may be due in part to the energy distribution across the coil. However, in disclosed embodiments the inductively coupled plasma utilized with processing chambers may include at least two separate coils arranged about the processing chamber. Disclosed embodiments may also include at least 4, 6, 8, 10, 20, etc. or more separate coils arranged about the processing chamber.

Portions of the coils may at least partially overlap one another in disclosed embodiments across a vertical cross-section of insulator section 850, and in embodiments the coils may be specifically arranged such that the portions contacting insulative section 850 do not overlap with a portion of any other electrode contacting a cross-sectional plane of insulative section 850. As illustrated, each coil may include a similar shape, and may be displaced about the processing chamber from other electrodes. For example, a two-electrode design may displace each electrode by about 180° from each other about the processing chamber. As would be understood, in chamber configurations comprising geometries other than circles, a hypothetical circle may be constructed about the chamber geometry to determine relative angles and displacement may be determined from there. Additionally, a four electrode design may displace each electrode by about 90° from each other about the processing chamber. A variety of other electrode configurations and displacement angles may be readily understood from these examples, and may include similar or dissimilar degrees of displacement amongst electrodes.

FIG. 9 shows a schematic cross-sectional view of a portion of an exemplary plasma generation device 900 according to the disclosed technology. As illustrated, plasma generation device 900 may be coupled with a processing chamber such as with an optional top plate 907. For example, any of the previously described chambers may be utilized with plasma generation device 900. The plasma generation device 900 may include a housing 910 containing all of the generation components, as well as a nozzle 920. Nozzle 920 may be positioned within the plasma generation device housing, and composed of an insulative material such as a ceramic, for example, in disclosed embodiments. The nozzle may include an injection port 930 through which one or more precursors may be delivered. An electrode 950 may be positioned within the plasma generation device housing 910, and coupled externally with nozzle 920, such as coiled about a portion of nozzle 920. In disclosed embodiments, the plasma electrode may include at least two or more separate coils arranged about the nozzle, such as previously described.

Plasma source 940 may be coupled with electrode 950 and utilized to generate a plasma within nozzle 920. The plasma source 940 may operate at any of the frequencies as previously described, and may for example operate at least at about 13.56 MHz or higher, such as 40 or 60 MHz, for example. Nozzle 920 may include multiple portions including an upper portion 922 and a lower portion 924. Electrode 950 may be coupled about one or more of the nozzle portions, and in embodiments may be coupled about upper portion 922. Such a configuration may be utilized to obviate multiple plasma sources used with a processing chamber. Power source 940 may be operated at a variety of frequencies to generate the requisite power for low-power operations, such as the etching operation previously described as well as high-powered operations such as the milling operation previously described. However, it may be difficult to generate an inductively coupled plasma at low-frequency, and thus in embodiments power source 940 may be operated at high-frequency, such as at least about 13.56 MHz, but pulsed in operation in order to provide a lower density or lower power plasma. In this way, plasma generation device 900 may be utilized successfully for plasma operations in which full ionization of precursors may not be desired.

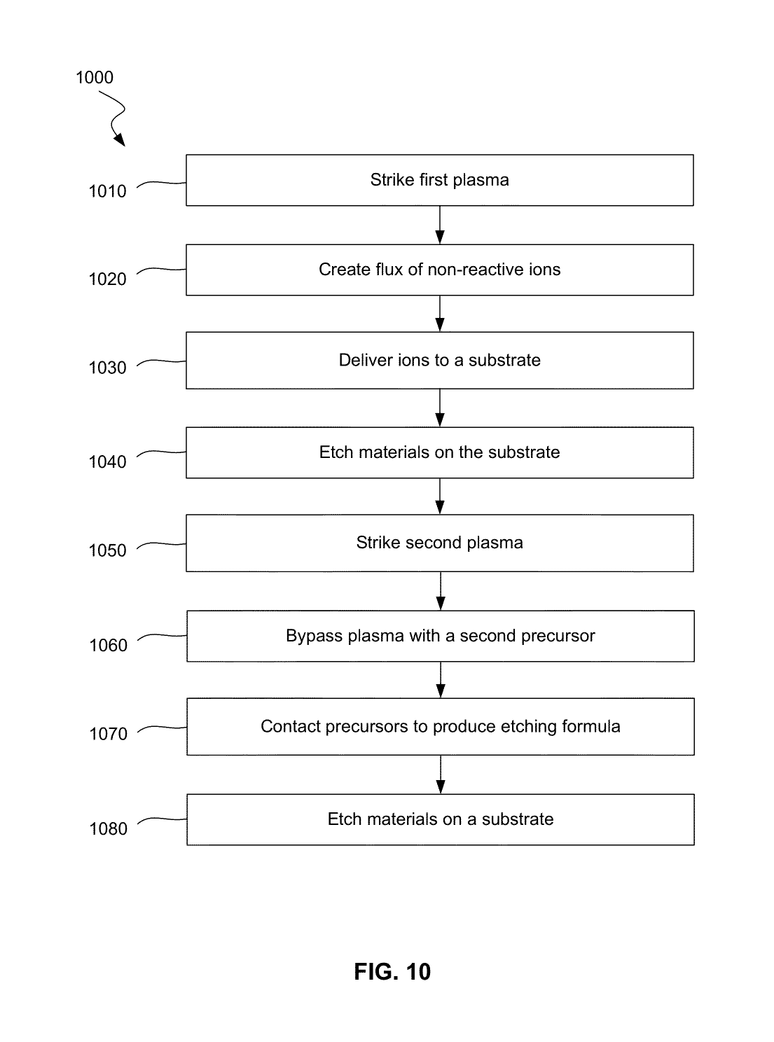

FIG. 10 shows a method 1000 of etching that may reduce film contamination or increase device throughput according to the present technology. Method 1000 may be performed in any of the systems previously described and may include optional operations including delivering a precursor for ionization to the system. Method 1000 may include striking a first plasma with a first plasma source comprising an inductively coupled plasma source in operation 1010, which may include an operating frequency previously described, and in one embodiment may be at least 13.56 or 60 MHz. The method may include creating a flux of nonreactive ions in operation 1020 such as from an ionization of the precursor being delivered which may include one or more precursors that may include argon, helium, hydrogen, nitrogen, and additional inert or reactive precursors.

The flux of nonreactive ions may be characterized by reduced bombardment of the system components based on the high-frequency electrical source utilized to produce the plasma. The flux of nonreactive ions may be delivered to a substrate housed in a processing chamber in operation 1030, and then may etch the substrate or materials on the substrate, such as with ion milling at operation 1040. The methods may include striking a second plasma at operation 1050 with a second plasma source separate from the first plasma source to create plasma effluents of a first precursor. In disclosed embodiments the second plasma source may be the same as the first plasma source, and may be operated at a different frequency or in a pulsed operation. At operation 1060, a second precursor may be delivered to the processing chamber and bypass the second plasma. The second precursor may be contacted with the plasma effluents of the first precursor to produce an etching formula at operation 1070.

An etching operation, such as a selective etching operation as previously described, may be performed with the etching formula on materials on a substrate housed within the processing chamber at operation 1080. By reducing system and chamber component bombardment, sputtering of chamber components or coatings, such as an electrode coating, may be reduced or prevented in embodiments. The sputtered particles may be carried through the system and deposited on the substrate being worked, which may result in short-circuiting or failure of the produced device. Accordingly, by utilizing the described methods increased device quality may be provided as well as increased chamber component life. Additionally, one or more of the electrodes utilized in the generation of the first plasma or second plasma may be maintained externally to the processing chamber, which may reduce degradation of the electrode due to plasma exposure.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an aperture” includes a plurality of such apertures, and reference to “the plate” includes reference to one or more plates and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing system comprising:
a processing chamber;
a first plasma source utilizing a first electrode positioned externally to the processing chamber, wherein the first plasma source is configured to generate a first plasma;
a second plasma source separate from the first plasma source, wherein the second plasma source utilizes a second electrode separate from the first electrode, wherein the second electrode is positioned externally to the processing chamber, and wherein the second plasma source is configured to generate a second plasma within the processing chamber; and
a first showerhead disposed between the relative locations of the first plasma electrode and the second plasma electrode.

2. The semiconductor processing system of claim 1, further comprising a second showerhead positioned fluidly downstream from the location in which the second plasma is configured to be generated.

3. The semiconductor processing system of claim 2, further comprising an insulator positioned between the first showerhead and the second showerhead.

4. The semiconductor processing system of claim 2, wherein the second showerhead comprises a multi-channel showerhead.

5. The semiconductor processing system of claim 1, wherein the second plasma source comprises an inductively coupled plasma source.

6. The semiconductor processing system of claim 5, wherein the inductively coupled plasma source comprises at least two separate coils arranged about the processing chamber.

7. The semiconductor processing system of claim 6, wherein the inductively coupled plasma source comprises at least four separate coils arranged about the processing chamber.

8. The semiconductor processing system of claim 7, wherein the at least four separate coils are displaced about the processing chamber from each other by about 90°.

9. The semiconductor processing system of claim 5, further comprising a second showerhead disposed fluidly upstream from the location in which the inductively coupled plasma is configured to be generated.

10. The semiconductor processing system of claim 1, wherein the first plasma source is electrically coupled with a first RF source.

11. The semiconductor processing system of claim 10, wherein the second plasma source is electrically coupled with a second RF source separate from the first RF source.

12. The semiconductor processing system of claim 11, wherein the first RF source is configured to operate at a first plasma frequency, and the second RF source is configured to operate at a second plasma frequency greater than the first plasma frequency.

13. A semiconductor processing system comprising:
a processing chamber having a top plate; and
a plasma generation device coupled with the top plate, wherein the plasma generation device comprises:
a plasma generation device housing,
a nozzle positioned within the plasma generation device housing, wherein the nozzle comprises a fluid injection port, and wherein the nozzle comprises an insulative material,
a plasma electrode positioned within the plasma generation device housing and coupled externally with the nozzle, wherein the plasma electrode is configured to generate a plasma within the nozzle.

14. The semiconductor processing system of claim 13, wherein the plasma electrode comprises at least two separate coils arranged about the nozzle.

15. An etching method, the method comprising:
striking a first plasma with a first plasma source comprising an inductively coupled plasma source;
creating a flux of non-reactive ions;
delivering the ions to a substrate;
etching materials on the substrate;
striking a second plasma with a second plasma source separate from the first plasma source to create plasma effluents of a first precursor;
bypassing the second plasma with a second precursor;
contacting the second precursor with the plasma effluents of the first precursor to produce an etching formula; and
etching materials on a substrate housed within a processing chamber with the etching formula.
